(19) United States
(12) Patent Application Publication
(10) Pub. No.: US 2003/0011276 A1
(43) Pub. Date: Jan. 16, 2003

(54) Arrangement for generating an operating voltage for an electric sub-assembly of a vehicle

(76) Inventor: Juergen Nowottnick, Hamburg (DE)

Correspondence Address: Michael E. Marion, c/o U.S. PHILIPS CORPORATION, Intellectual Property Department, 580 White Plains Road, Tarrytown, NY, 10591, US

(21) Appl. No.: 10/188,675

(22) Filed: Jul. 3, 2002

(30) Foreign Application Priority Data
Jul. 10, 2001 (DE) 10133493.1

(51) Int. Cl. H01L 41/08; B60L 1/00

(52) U.S. Cl. 310/311; 180/65.1; 320/107

(57) ABSTRACT

An arrangement according to the invention for generating an operating voltage for at least one electric sub-assembly (5) of a vehicle with a wheel/tire comprises a piezoelectric element (3) which is arranged in such a way that it is caused to oscillate as a result of tire pressure fluctuations occurring when the vehicle is in motion. The then occurring alternating output voltage of the piezoelectric element (3) is used for the power supply of the electric sub-assembly (5).

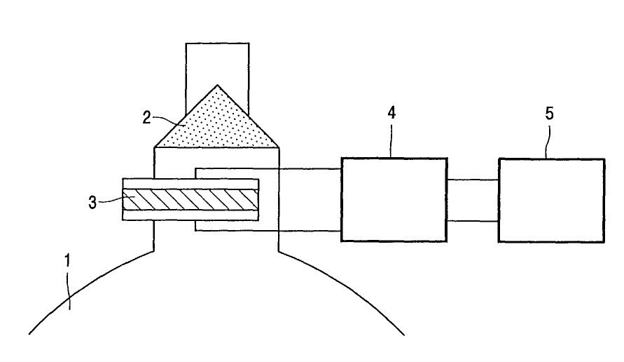

The invention relates to an arrangement for generating an operating voltage for at least one electric sub-assembly of a vehicle. The vehicle has at least a wheel with a tire which is filled with air or another gas.

Batteries or accumulators are generally used for the power supply of such electric sub-assemblies, which are mounted on a car tire. Such sub-assemblies may be, for example, sensors for measuring the tire pressure or the tire temperature. The power supply of such sub-assemblies by means of batteries or accumulators has various drawbacks. Batteries or accumulators are often uneconomical and have a limited lifetime. They may even have to be exchanged during the lifetime of the vehicle. Since rotating parts are concerned, it is difficult to comply with the strict requirements on the reliability of the power supply when using batteries or accumulators.

It is an object of the invention to provide an arrangement of the type described in the opening paragraph for generating an operating voltage, which arrangement is reliable and does not require any exchange of parts.

According to the invention, this object is solved by the characteristic features defined in claim 1:

An arrangement for generating an operating voltage for at least one electric sub-assembly which is arranged on a vehicle wheel with a tire, the arrangement comprising a piezoelectric element which is arranged in such a way that it is caused to oscillate as a result of tire pressure fluctuations occurring when the vehicle is in motion, and whose alternating output voltage then occurring is usable for the power supply of the electric sub-assembly.

A vehicle with an electric sub-assembly which is mounted on a wheel and is to be supplied with an operating voltage has a tire filled with air or a similar gas. When the vehicle is in motion, air pressure fluctuations, caused by unevenness of the road, occur in the tire of the vehicle. These fluctuations are utilized in the arrangement according to the invention by means of the piezoelectric element in such a way that the tire pressure fluctuations cause the piezoelectric element to oscillate. This then generates an electric voltage which can be used for the power supply of at least one electric sub-assembly in the vehicle, particularly on the wheel of the vehicle. The piezoelectric element operates in an extremely reliable manner and generates a voltage which is based on a fluctuating mechanical pressure which is exerted on the element. In the arrangement according to the invention, this fluctuating pressure is generated by the fluctuating filling pressure of the tire when the vehicle is in motion.

The arrangement according to the invention generates an operating voltage in a completely autonomous manner for the electric sub-assembly and does not require any batteries, accumulators or the like. Moreover, such a piezoelectric element has an unlimited lifetime so that the arrangement according to the invention is suitable throughout the life of a vehicle or a wheel/tire without any exchange of parts.

The arrangement according to the invention can be realized at low cost. It allows a decentral power supply of the sensor electronic equipment on the wheel/tire of the vehicle without any connection thereto.

In further embodiments of the invention as defined in claims 2 and 3, the piezoelectric element may be advantageously arranged on a valve of the tire or in the cover of the tire. In both cases, the fluctuating filling pressure of the tire may be used for generating oscillations of the piezoelectric element.

In a further embodiment of the invention as defined in claim 4, the output signal of the piezoelectric element may be processed by means of an electronic processing component which then ensures the power supply of the electric sub-assembly on the wheel. Such a processing component may be, for example, a voltage controller or a rectifier circuit.

In principle, the piezoelectric element only supplies a voltage when the vehicle is in motion and when fluctuations of the filling pressure in the tire thus occur. To ensure also power supply when the vehicle is not in motion, the arrangement, as defined by a further embodiment of the invention in claim 6, may comprise an accumulator which is charged by means of the voltage supplied by the piezoelectric element and ensures power supply of the electric sub-assembly, also when the vehicle is not in motion.

As defined in claim 7, the electric sub-assembly may be, for example, a tire pressure sensor and/or a tire temperature sensor. Such sensors are increasingly being used in vehicles. The problem occurs that these sensors must be designed for the lifetime of the car and/or the wheel and must be coupled to an autonomously operating power supply. It is exactly these conditions that are fulfilled by the arrangement according to the invention.

These and other aspects of the invention are apparent from and will be elucidated with reference to the embodiments described hereinafter.

In the drawing:

The sole FIGURE shows diagrammatically a tire 1 of a vehicle (not shown). The tire 1 is mounted on a wheel of the vehicle and filled with a gas, generally air.

When the vehicle is in motion, the wheel with the tire 1 is rotated and rolls on a ground, usually a road. Every ground has at least slight unevennesses which lead to flexing of the air-filled tire 1, i.e. it is indented to a greater or smaller degree in the area of the contact surface so that the inner pressure of the tire fluctuates to a small extent.

The arrangement according to the invention comprises a piezoelectric element 3. In the FIGURE, the piezoelectric element 3 is provided in a valve 2 of the tire, which valve is used for filling the tire 1 with air and therefore directly communicates with the air filling of the tire 1.

The piezoelectric element 3 is arranged in the valve 2 of the tire 1 in such a way that it is brought to slight motions when the above-mentioned air pressure fluctuations occur in the tire 1, i.e. in such a way that it is subjected to the air pressure fluctuations. As a result of these pressure fluctuations, the piezoelectric element 3 generates an electric voltage, which is an alternating voltage.

The FIGURE shows diagrammatically that this electric voltage is taken from the two end plates of the piezoelectric element 3 and is applied to an electronic processing component 4.

The electronic processing component 4 may, for example, rectify the alternating voltage supplied by the piezoelectric element 3. A simple voltage control of the alternating voltage may also be performed in the electronic processing component 4. Furthermore, a kind of accumulator may be provided in the electronic processing component 4, which accumulator is charged with the rectified alternating voltage supplied by the piezoelectric element 3 and supplies a direct output voltage for the tire 1, also when the vehicle is not in motion.

The electronic processing component 4 is coupled to an electric sub-assembly 5 which is only shown diagrammatically in the FIGURE and may be, for example, a tire pressure sensor or a tire temperature sensor.

Such sensors are increasingly being used in tires and require an autonomous power supply, i.e. a power supply which is not coupled to the supply system of the vehicle.

When such a sensor is used, it is mounted on the tire or in the wheel in the manner which is not further shown in the FIGURE.

The arrangement according to the invention, as shown in the FIGURE, operates completely autonomously, i.e. it does not require any connection with the supply system (not shown) of the vehicle. In principle, the piezoelectric element 3 has an unlimited lifetime, i.e. an exchange of an element in the arrangement is not required during the life of the vehicle and/or the wheel/tire. The arrangement has a very simple structure and is therefore reliable and inexpensive.

1. An arrangement for generating an operating voltage for at least one electric sub-assembly (5) which is arranged on a vehicle wheel with a tire (1), the arrangement comprising a piezoelectric element (3) which is arranged in such a way that it is caused to oscillate as a result of tire pressure fluctuations occurring when the vehicle is in motion, and whose alternating output voltage then occurring is usable for the power supply of the electric sub-assembly (5).

2. An arrangement as claimed in claim 1, characterized in that the piezoelectric element (3) is arranged on a valve (2) of the tire (1).

3. An arrangement as claimed in claim 1, characterized in that the piezoelectric element (3) is arranged in the cover of the tire (1).

4. An arrangement as claimed in any one of claims 1 to 3, characterized in that the output signal of the piezoelectric element (3) is applied to a processing electronic component (4) such as, for example, a rectifier, a voltage controller or a charge capacitor which ensures the power supply of the electric sub-assembly (5).

5. An arrangement as claimed in any one of claims 1 to 4, characterized in that the piezoelectric element (3) is also used for measuring the tire pressure.

6. An arrangement as claimed in any one of claims 1 to 5, characterized in that the arrangement comprises an accumulator which is charged by means of the voltage supplied and rectified by the piezoelectric element (3) and supplies the power supply voltage for the electric sub-assembly.

7. An arrangement as claimed in any one of claims 1 to 5, characterized in that the electric sub-assembly (5) is a tire pressure sensor and/or a tire temperature sensor.
